(19) United States
(12) Patent Application Publication
(10) Pub. No.: US 2015/0137094 A1
(43) Pub. Date: May 21, 2015

(54) MATERIAL FOR ORGANIC ELECTROLUMINESCENCE DEVICE AND ORGANIC ELECTROLUMINESCENCE DEVICE USING THE SAME

(71) Applicant: SAMSUNG DISPLAY CO., LTD., Yongin-City (KR)

(72) Inventors: Hiroaki ITOI, Yokohama (JP); Yasuo MIYATA, Yokohama (JP)

(21) Appl. No.: 14/516,118

(22) Filed: Oct. 16, 2014

(30) Foreign Application Priority Data
Nov. 21, 2013 (JP) 2013-241333

(51) Int. Cl. H01L 51/00

(52) U.S. Cl. CPC H01L 51/0072; H01L 51/5012
USPC 257/40; 548/445

(57) ABSTRACT

A material for an organic electroluminescence (EL) device and an organic electroluminescence (EL) device, the material being represented by Formula 1:

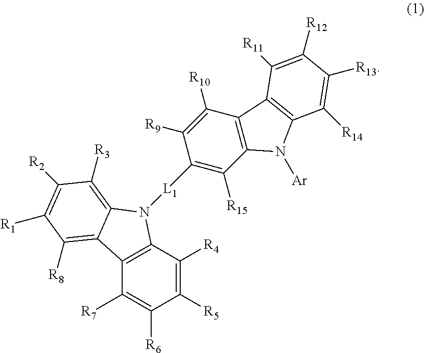

### CROSS-REFERENCE TO RELATED APPLICATION

Japanese Patent Application No. 2013-241333, filed on Nov. 21, 2013, in the Japanese Patent Office, and entitled: “Material for Organic Electroluminescence Device and Organic Electroluminescence Device Using the Same,” is incorporated by reference herein in its entirety.

### BACKGROUND

1. Field

Embodiments relate to a material for an organic electroluminescence device and an electroluminescence device using the same.

2. Description of the Related Art

In recent years, organic electroluminescence (EL) displays are one type of image displays that have been actively developed. Unlike a liquid crystal display and the like, the organic EL display is a self-luminescent display that recombines holes and electrons injected from a positive electrode and a negative electrode in an emission layer to thus emit lights from a light-emitting material (including an organic compound of the emission layer), thereby performing display.

An example of an organic electroluminescence device (hereinafter referred to as an organic EL device) may include an organic EL device including a positive electrode, a hole transport layer on the positive electrode, an emission layer on the hole transport layer, an electron transport layer on the emission layer, and a negative electrode on the electron transport layer. Holes injected from the positive electrode may be injected into the emission layer via the hole transport layer. Meanwhile, electrons may be injected from the negative electrode, and then injected into the emission layer via the electron transport layer. The holes and the electrons injected into the emission layer may be recombined to generate excitons within the emission layer. The organic EL device may emit light by using lights generated by the radiation and deactivation of the excitons. The organic EL device may be changed in various forms.

### SUMMARY

Embodiments are directed to a material for an organic electroluminescence device and an electroluminescence device using the same.

The embodiments may be realized by providing a material for an organic electroluminescence (EL) device, the material being represented by Formula 1:

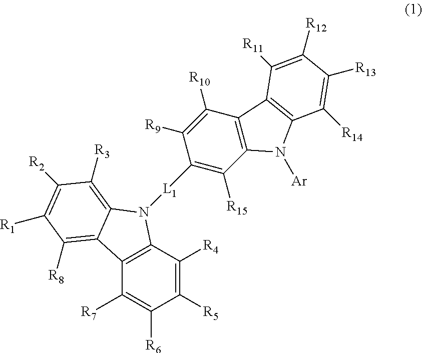

wherein, in Formula 1, Ar is an aryl group having 6 to 30 ring carbon atoms, a heteroaryl group having 1 to 30 ring carbon atoms, or an alkyl group having 1 to 15 carbon atoms, R₁ to R₁₅ are each independently an aryl group having 6 to 30 ring carbon atoms a heteroaryl group having 1 to 30 ring carbon atoms, an alkyl group having 1 to 15 carbon atoms, a halogen atom, a hydrogen atom, or a deuterium atom, and L₁ is a divalent connecting group.

A plurality of adjacent ones of R₁ to R₁₄ may be bound to each other and form a saturated or unsaturated ring.

The embodiments may be realized by providing a material for an organic electroluminescence (EL) device, the material being represented by Formula 2:

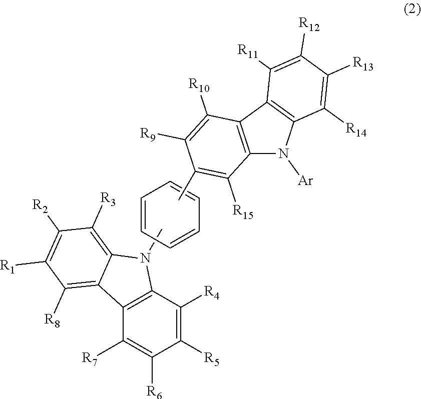

wherein, in Formula 2, Ar is an aryl group having 6 to 30 ring carbon atoms, a heteroaryl group having 1 to 30 ring carbon atoms, or an alkyl group having 1 to 15 carbon atoms, and R₁ to R₁₅ are each independently an aryl group having 6 to 30 ring carbon atoms, a heteroaryl group having 1 to 30 ring carbon atoms, an alkyl group having 1 to 15 carbon atoms, a halogen atom, a hydrogen atom, or a deuterium atom.

A plurality of adjacent ones of R₁ to R₁₄ may be bound to each other and form a saturated or unsaturated ring.

The embodiments may be realized by providing an organic electroluminescence (EL) device including the material for an organic EL device according to an embodiment in an emission layer or in a layer among layers stacked between the emission layer and a positive electrode.

### BRIEF DESCRIPTION OF THE DRAWING

Features will be apparent to those of skill in the art by describing in detail exemplary embodiments with reference to the attached drawing in which:

FIG. 1 illustrates a schematic diagram of the structure of an organic EL device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

The driving at a low voltage and the improvement of the hole transporting properties and the electron tolerance of an organic EL device may be expected by introducing two heat resistant carbazole parts having hole transport properties through a connecting group. For the use of a compound introducing two carbazole parts through the connecting group as a material for a layer between an emission layer and a positive electrode, a highest occupied molecular orbital (HOMO) level may be lowered but not to the level of an emission layer. The driving at a markedly low driving voltage, high efficiency and long life of an organic EL device may be realized by combining a carbon atom at position 2 of one carbazole part with a nitrogen atom at position 9 of the other carbazole part.

Hereinafter, a material for an organic EL device and an organic EL device using the same according to exemplary embodiments will be described in detail with reference to the accompanying drawing.

The material for an organic EL device according to an embodiment may include a compound in which two carbazole parts or moieties are combined or bound through a connecting group, as illustrated in the following Formula 1.

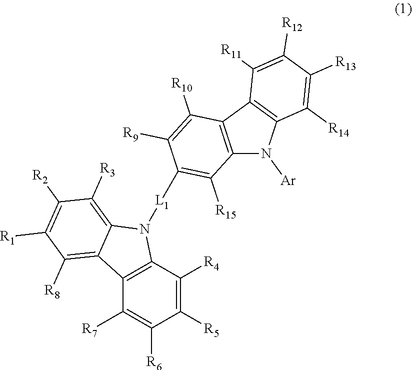

In Formula 1, Ar may be an aryl group having 6 to 30 carbon atoms for forming a ring, e.g., ring carbon atoms, a heteroaryl group having 1 to 30 carbon atoms for forming a ring, e.g., ring carbon atoms, or an alkyl group having 1 to 15 carbon atoms. R₁ to R₁₅ may each independently be an aryl group having 6 to 30 carbon atoms for forming a ring, e.g., ring carbon atoms, a heteroaryl group having 1 to 30 carbon atoms for forming a ring, e.g., ring carbon atoms, an alkyl group having 1 to 15 carbon atoms, a halogen atom, a hydrogen atom, or a deuterium atom. L₁ may be a divalent connecting group.

The material for an organic EL device according to an embodiment may exhibit hole transport properties and may have improved hole transport properties and electron tolerance by introducing two heat resistant carbazole moieties and combining carbon at position 2 of one carbazole moiety with nitrogen at position 9 of the other carbazole moiety through a connecting group. HOMO level may not be lowered to a desired level by combining or bonding to carbon at position 3 of the one carbazole moiety.

In an implementation, substituent Ar (on the nitrogen at position 9 of the other carbazole moiety) may be an aryl group having 6 to 30 carbon atoms, e.g., ring carbon atoms, a heteroaryl group having 1 to 30 carbon atoms, e.g., ring carbon atoms, or an alkyl group having 1 to 15 carbon atoms.

Ar may include, e.g., a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group, a dibenzothienyl group, or the like.

In an implementation, Ar may be a group represented by one of the following groups a-1 to a-12.

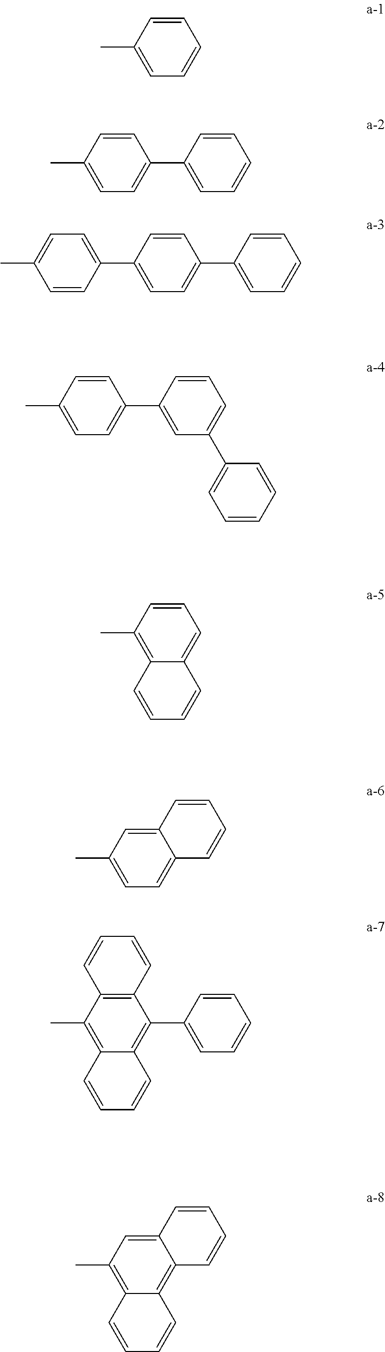

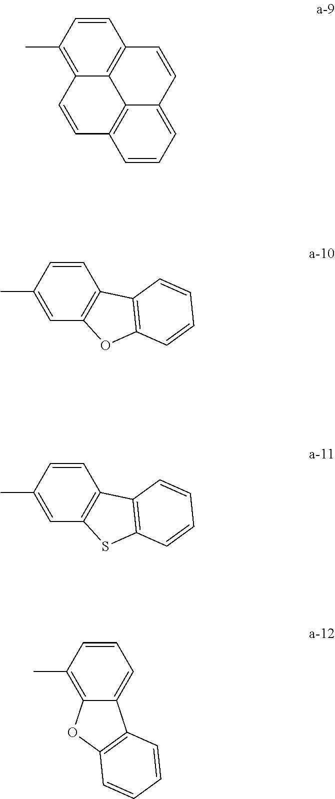

In an implementation, the connecting group (L₁) may include, e.g., a substituted or unsubstituted arylene group having 6 to 30 carbon atoms, e.g., ring carbon atoms. In an implementation, the connecting group (L₁) may include, e.g., a phenylene group, a biphenylene group, a naphthylene group, a diphenylbenzene diyl group, an anthracenyl group, or the like. In an implementation, the connecting group (L₁) may include, e.g., a phenylene group.

In an implementation, the divalent connecting group (L₁) may include, e.g., a group represented by one of the following groups b-1 to b-12.

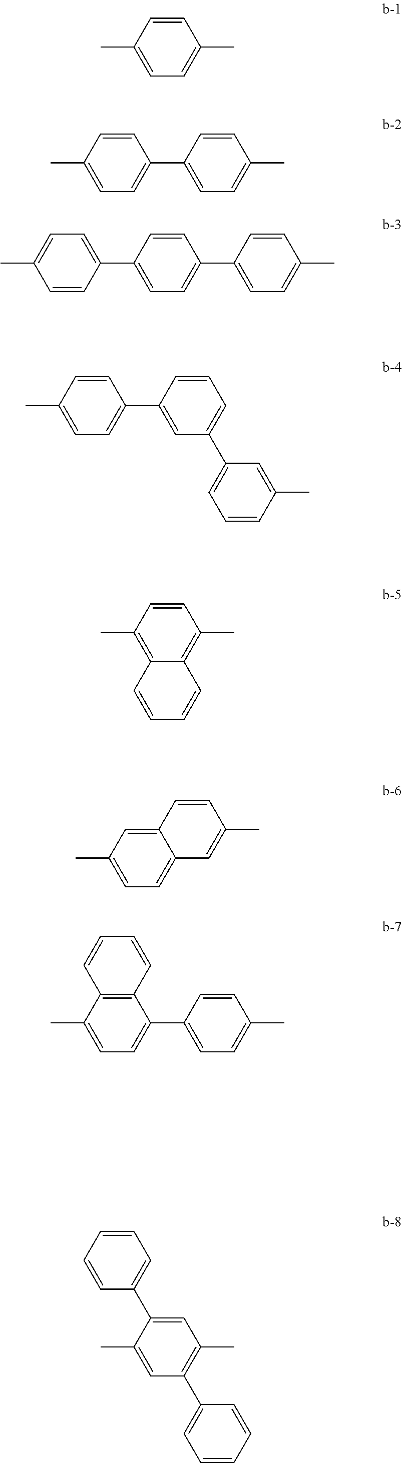

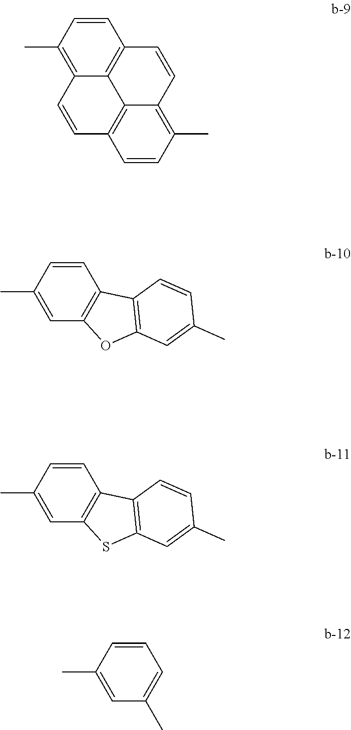

In an implementation, R₁ to R₁₅ may each independently be an aryl group having 6 to 30 carbon atoms, e.g., ring carbon atoms, a heteroaryl group having 1 to 30 carbon atoms, e.g., ring carbon atoms, an alkyl group having 1 to 15 carbon atoms, a halogen atom, a hydrogen atom, or a deuterium atom. In an implementation, R₁ to R₁₅ may be the same or different, and at least two of them may be the same substituent.

In an implementation, R₁ to R₁₅ may each independently include, e.g., a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, a 1-pyrrolyl group, a 2-pyrrolyl group, a 3-pyrrolyl group, a pyradinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-fenoxadinyl group, a 2-fenoxadinyl group, a 3-fenoxadinyl group, a 4-fenoxadinyl group, a 10-fenoxadinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrol-1-yl group, a 2-methylpyrrol-3-yl group, a 2-methylpyrrol-4-yl group, a 2-methylpyrrol-5-yl group, a 3-methylpyrrol-1-yl group, a 3-methylpyrrol-2-yl group, a 3-methylpyrrol-4-yl group, a 3-methylpyrrol-5-yl group, a 2-t-butylpyrrol-4-yl group, a 3-(2-phenylpropyl)pyrrol-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, a methyl group, an ethyl group, a propyl group, an isopropyl group, an n-butyl group, a s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydorxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-triboromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, or the like.

In an implementation, Ar may be, e.g., a group represented by one of the following groups c-1 to c-16.

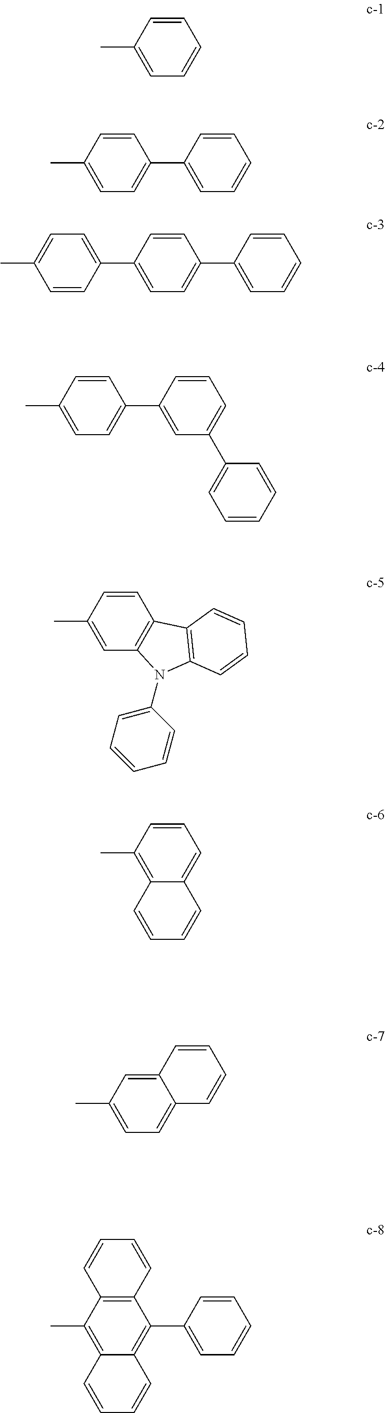

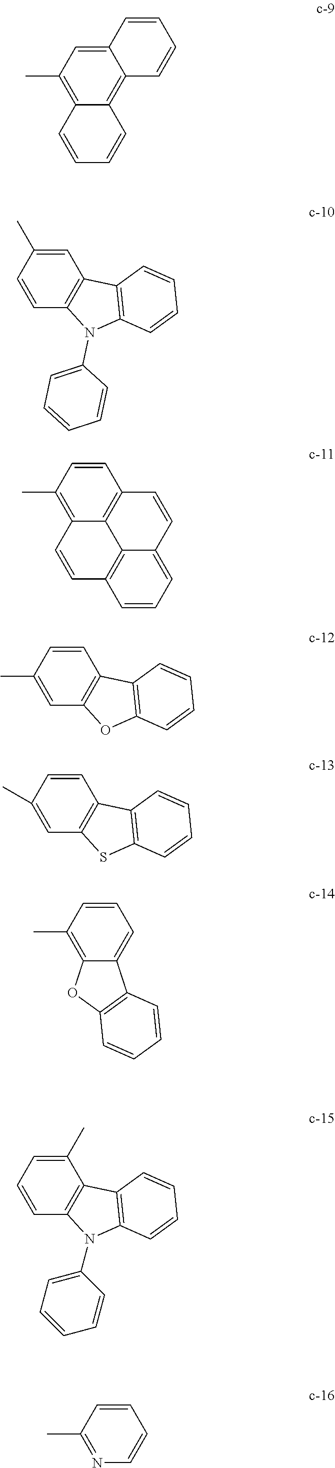

In an implementation, Ar may be, e.g., a group represented by one of the following groups c-17 to c-25.

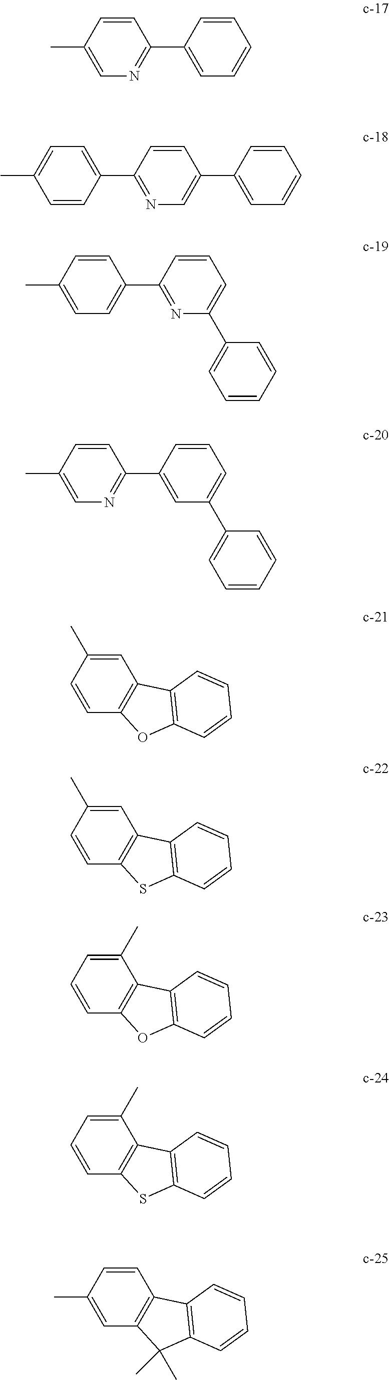

In an implementation, the material for an organic EL device according to an embodiment may be, e.g., a triarylamine derivative compound, represented by the following Formula 2.

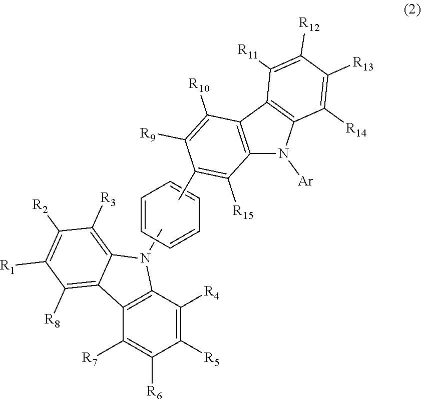

For example, a phenylene group may be used as the divalent connecting group (L₁) in the material for the organic EL device. In addition, by combining carbon at position 2 of one carbazole moiety with nitrogen at position 9 of the other carbazole moiety via a phenylene group in the material for an organic EL device according to an embodiment, hole transporting properties and electron tolerance may be improved.

In Formula 2, Ar may be, e.g., an aryl group having 6 to 30 carbon atoms, e.g., ring carbon atoms, a heteroaryl group having 1 to 30 carbon atoms, e.g., ring carbon atoms, or an alkyl group having 1 to 15 carbon atoms. In the material for an organic EL device according to an embodiment, an aryl group having 6 to 30 carbon atoms, e.g., ring carbon atoms, a heteroaryl group having 1 to 30 carbon atoms, e.g., ring carbon atoms, or an alkyl group having 1 to 15 carbon atoms may be introduced at the nitrogen at position 9 of one carbazole moiety. Examples of particular substituents may be the same as those described above with respect to Formula 1, and repeated detailed descriptions thereof may be omitted.

In an implementation, R₁ to R₁₅ may each independently be an aryl group having 6 to 30 carbon atoms, e.g., ring carbon atoms, a heteroaryl group having 1 to 30 carbon atoms, e.g., ring carbon atoms, an alkyl group having 1 to 15 carbon atoms, a halogen atom, a hydrogen atom, or a deuterium atom. R₁ to R₁₅ may be the same or different, and at least two thereof may be the same substituent.

Examples of particular substituents of R₁ to R₁₅ may be the same as those described above with respect to Formula 1, and repeated detailed description thereof may be omitted.

In the material for an organic EL device according to an embodiment, any adjacent ones of R₁ to R₁₄ may be combined together or bound and may form a saturated or unsaturated ring.

The material for an organic EL device according to an embodiment may have the above described structure, the driving of the organic EL device at a low voltage may be realized, and hole transporting properties and electron tolerance may be improved. Thus, the long life and the high efficiency of the organic EL device may be realized.

In an implementation, the material for the organic EL device may be one of Compounds 1 to 6, below.

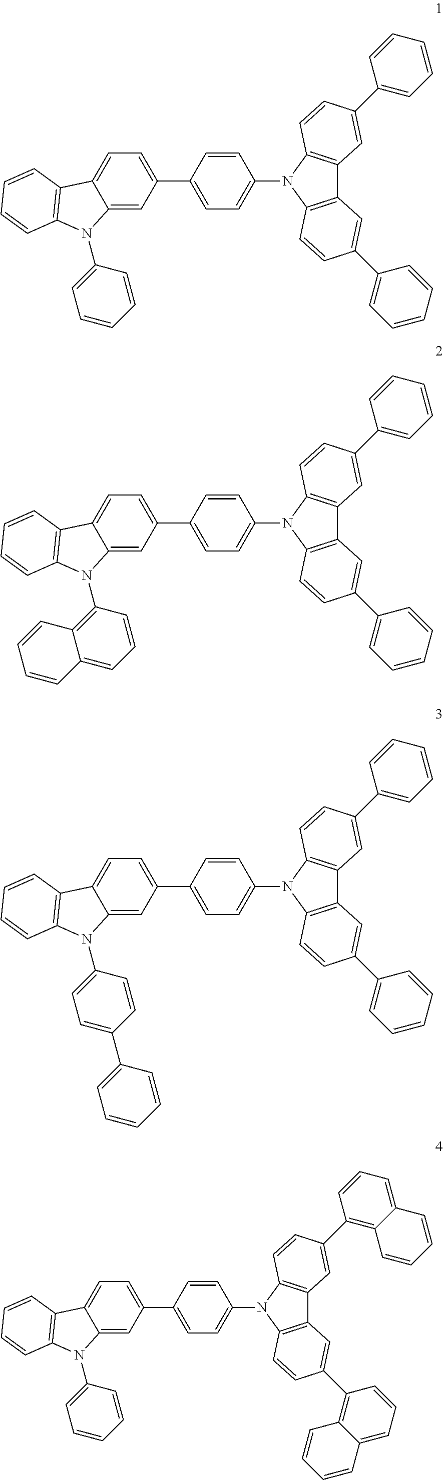 [SMILES: c1ccc(-c2ccc3c(c2)c2cc(-c4ccccc4)ccc2n3-c2ccc(-c3ccc4c5ccccc5n(-c5ccccc5)c4c3)cc2)cc1 ; c1ccc(-c2ccc3c(c2)c2cc(-c4ccccc4)ccc2n3-c2ccc(-c3ccc4c5ccccc5n(-c5cccc6ccccc56)c4c3)cc2)cc1 ; c1ccc(-c2ccc(-n3c4ccccc4c4ccc(-c5ccc(-n6c7ccc(-c8ccccc8)cc7c7cc(-c8ccccc8)ccc76)cc5)cc43)cc2)cc1 ; c1ccc(-n2c3ccccc3c3ccc(-c4ccc(-n5c6ccc(-c7cccc8ccccc78)cc6c6cc(-c7cccc8ccccc78)ccc65)cc4)cc32)cc1]

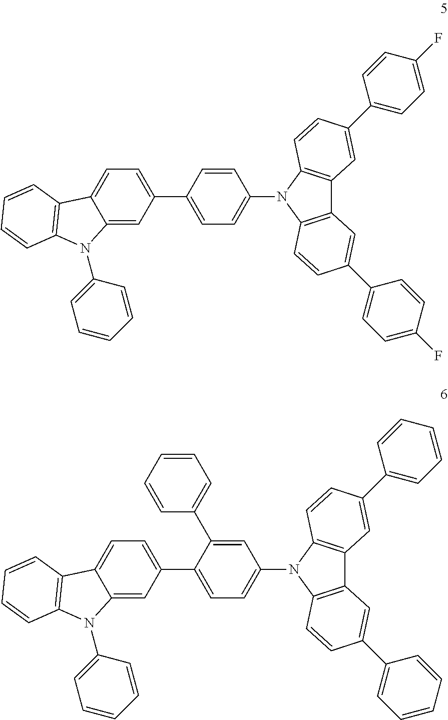 [SMILES: Fc1ccc(-c2ccc3c(c2)c2cc(-c4ccc(F)cc4)ccc2n3-c2ccc(-c3ccc4c5ccccc5n(-c5ccccc5)c4c3)cc2)cc1 ; c1ccc(-c2ccc3c(c2)c2cc(-c4ccccc4)ccc2n3-c2ccc(-c3ccc4c5ccccc5n(-c5ccccc5)c4c3)c(-c3ccccc3)c2)cc1]

In an implementation, the material for the organic EL device may be one of Compounds 7 to 12, below.

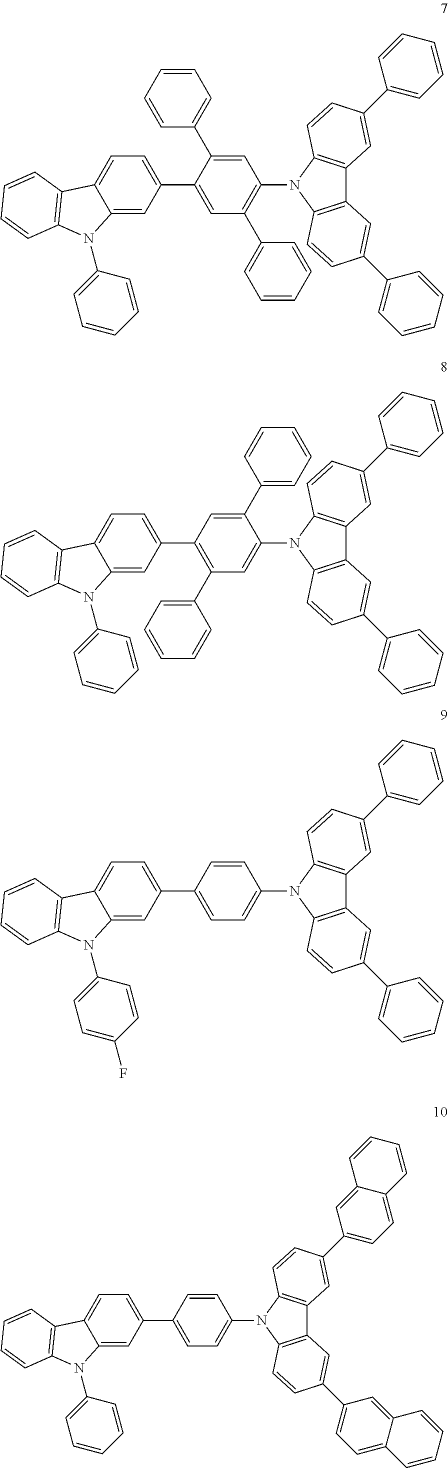

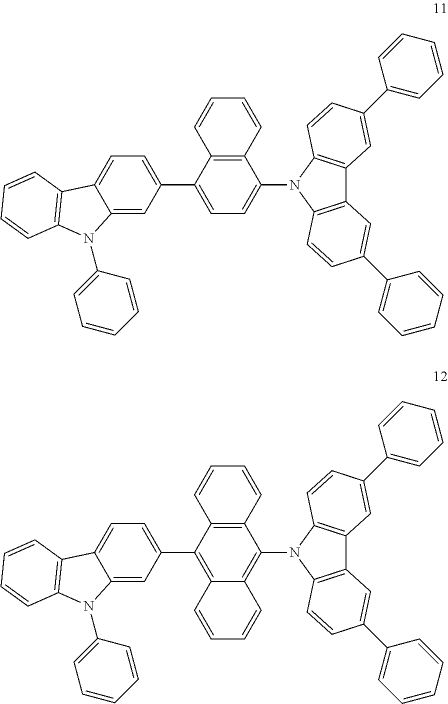 [SMILES: c1ccc(-c2ccc3c(c2)c2cc(-c4ccccc4)ccc2n3-c2ccc(-c3ccc4c5ccccc5n(-c5ccccc5)c4c3)c3ccccc23)cc1 ; c1ccc(-c2ccc3c(c2)c2cc(-c4ccccc4)ccc2n3-c2c3ccccc3c(-c3ccc4c5ccccc5n(-c5ccccc5)c4c3)c3ccccc23)cc1]

In an implementation, the material for the organic EL device may be one of Compounds 13 to 18, below.

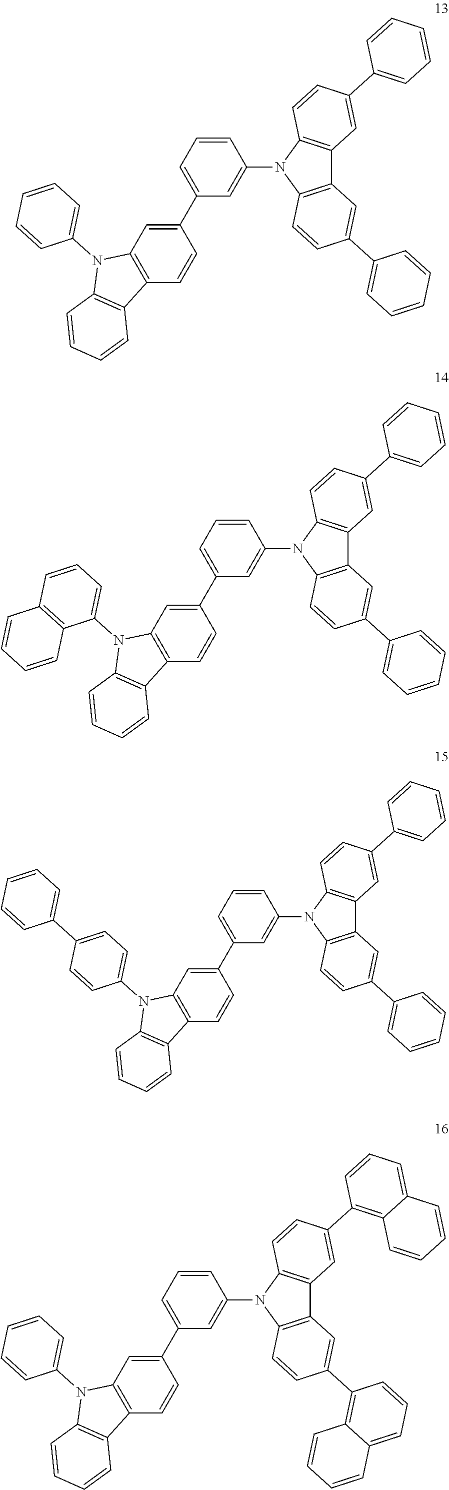 [SMILES: c1ccc(-c2ccc3c(c2)c2cc(-c4ccccc4)ccc2n3-c2cccc(-c3ccc4c5ccccc5n(-c5ccccc5)c4c3)c2)cc1 ; c1ccc(-c2ccc3c(c2)c2cc(-c4ccccc4)ccc2n3-c2cccc(-c3ccc4c5ccccc5n(-c5cccc6ccccc56)c4c3)c2)cc1 ; c1ccc(-c2ccc(-n3c4ccccc4c4ccc(-c5cccc(-n6c7ccc(-c8ccccc8)cc7c7cc(-c8ccccc8)ccc76)c5)cc43)cc2)cc1 ; c1ccc(-n2c3ccccc3c3ccc(-c4cccc(-n5c6ccc(-c7cccc8ccccc78)cc6c6cc(-c7cccc8ccccc78)ccc65)c4)cc32)cc1]

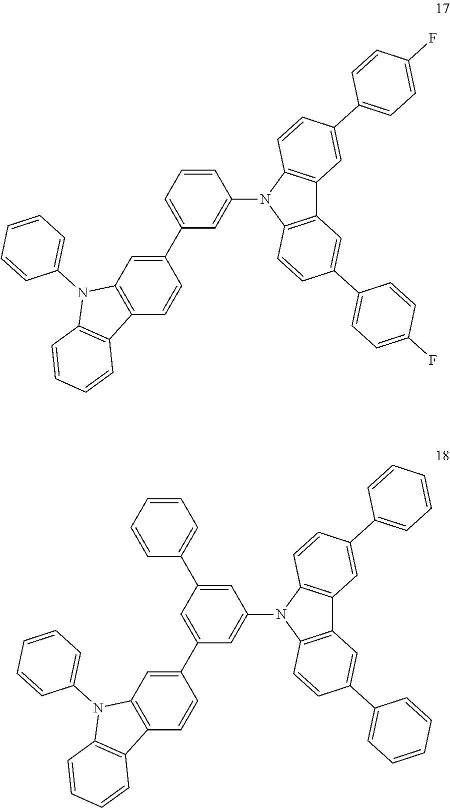 [SMILES: Fc1ccc(-c2ccc3c(c2)c2cc(-c4ccc(F)cc4)ccc2n3-c2cccc(-c3ccc4c5ccccc5n(-c5ccccc5)c4c3)c2)cc1 ; c1ccc(-c2cc(-c3ccc4c5ccccc5n(-c5ccccc5)c4c3)cc(-n3c4ccc(-c5ccccc5)cc4c4cc(-c5ccccc5)ccc43)c2)cc1]

In an implementation, the material for the organic EL device may be one of Compounds 19 to 24, below.

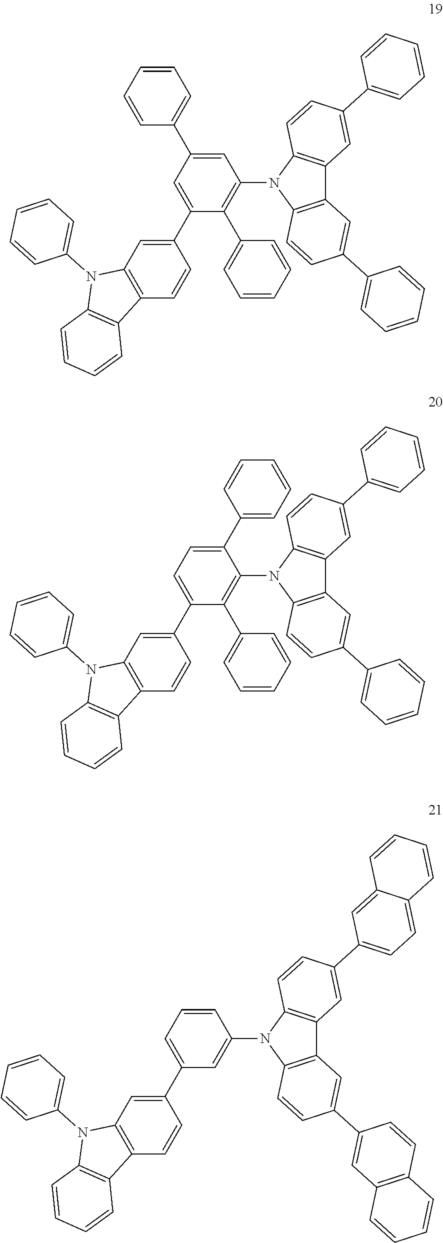 [SMILES: c1ccc(-c2cc(-c3ccc4c5ccccc5n(-c5ccccc5)c4c3)c(-c3ccccc3)c(-n3c4ccc(-c5ccccc5)cc4c4cc(-c5ccccc5)ccc43)c2)cc1 ; c1ccc(-c2ccc3c(c2)c2cc(-c4ccccc4)ccc2n3-c2c(-c3ccccc3)ccc(-c3ccc4c5ccccc5n(-c5ccccc5)c4c3)c2-c2ccccc2)cc1 ; c1ccc(-n2c3ccccc3c3ccc(-c4cccc(-n5c6ccc(-c7ccc8ccccc8c7)cc6c6cc(-c7ccc8ccccc8c7)ccc65)c4)cc32)cc1]

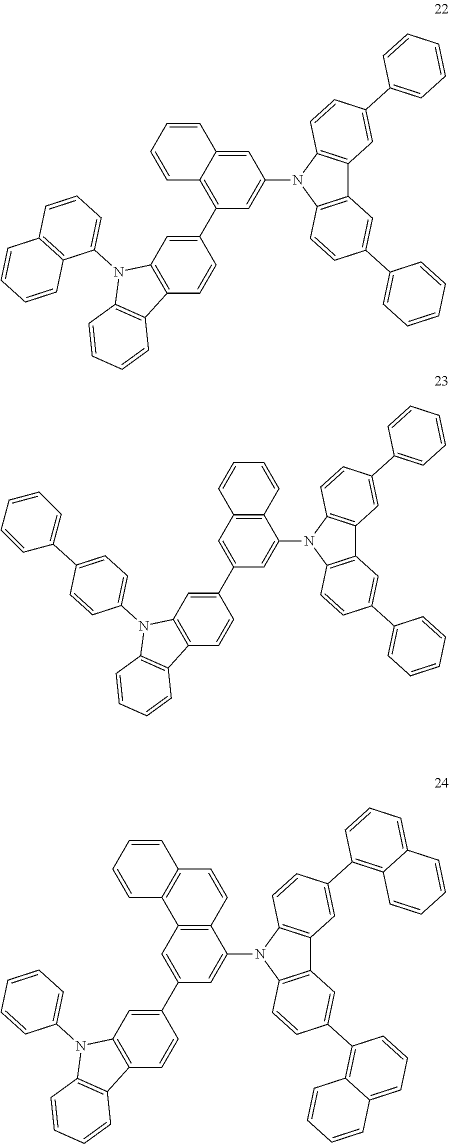 [SMILES: c1ccc(-c2ccc3c(c2)c2cc(-c4ccccc4)ccc2n3-c2cc(-c3ccc4c5ccccc5n(-c5cccc6ccccc56)c4c3)c3ccccc3c2)cc1 ; c1ccc(-c2ccc(-n3c4ccccc4c4ccc(-c5cc(-n6c7ccc(-c8ccccc8)cc7c7cc(-c8ccccc8)ccc76)c6ccccc6c5)cc43)cc2)cc1 ; c1ccc(-n2c3ccccc3c3ccc(-c4cc(-n5c6ccc(-c7cccc8ccccc78)cc6c6cc(-c7cccc8ccccc78)ccc65)c5ccc6ccccc6c5c4)cc32)cc1]

The material for an organic EL device according to an embodiment may be used or included in an emission layer of an organic device. In addition, the material for an organic EL device according to an embodiment may be used or included in a layer among layers stacked between an emission layer and a positive electrode. Thus, hole transporting properties may be improved, and the driving of the organic EL device at a low voltage with high efficiency may be realized.

(Organic EL Device)

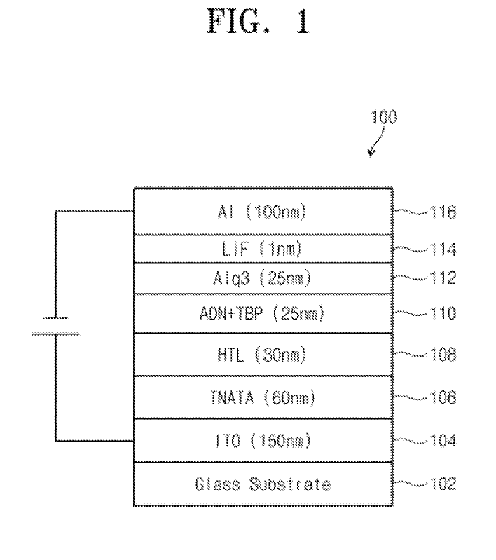

An organic EL device using the material for an organic EL device according to an embodiment will be explained. FIG. 1 illustrates a schematic diagram of the configuration of an organic EL device 100 according to an embodiment. The organic EL device 100 may include, e.g., a substrate 102, a positive electrode 104, a hole injection layer 106, a hole transport layer 108, an emission layer 110, an electron transport layer 112, an electron injection layer 114, and a negative electrode 116. In an implementation, the material for an organic EL device described above may be used or included in the emission layer 110 of the organic EL device 100. In an implementation, the material for an organic EL device described above may be used or included in one layer among the layers stacked between the emission layer 110 and the positive electrode 104, e.g., the hole injection layer 106 or the hole transport layer 108.

For example, an embodiment including the material for an organic EL device according to an embodiment in the hole transport layer 108 will be explained. The substrate 102 may be a transparent glass substrate, a semiconductor substrate formed by using silicon, or the like, or a flexible substrate formed by using a resin. The positive electrode 104 may be on the substrate 102 and may be formed by using, e.g., indium tin oxide (ITO), indium zinc oxide (IZO), or the like. The hole injection layer 106 may be on the positive electrode 104 and may include, e.g., 4,4′,4″-tris(N-1-naphthyl)-N-phenylamino)-triphenylamine (1-TNATA) or 4,4-bis[N,N-di(3-tolyl)amino]-3,3-dimethylbiphenyl (HMTPD), or the like. The hole transport layer 108 may be on the hole injection layer 106, and may be formed by using the material for an organic EL device according to an embodiment. The emission layer 110 may be on the hole transport layer 108, and may be formed by using the material for an organic EL device according to an embodiment. In an implementation, the emission layer 110 may be formed by doping tetra-t-butylperylene (TBP) in a host material including, e.g., 9,10-di(2-naphthyl)anthracene (ADN). The electron transport layer 112 may be on the emission layer 110, and may be formed by using, e.g., tris(8-hydroxyquinolinato)aluminum (Alq3). The electron injection layer 114 may be on the electron transport layer 112, and may be formed by using a material including, e.g., lithium fluoride (LiF). The negative electrode 116 may be on the electron injection layer 114, and is formed by using a metal such as Al or a transparent material such as ITO, IZO, or the like. The above-described layers may be formed by selecting a suitable layer forming method such as vacuum deposition, sputtering, various coatings, or the like.

In the organic EL device 100 according to this embodiment, a hole transport layer 108 realizing driving at a low voltage and high efficiency may be formed by using the material for an organic EL device according to an embodiment. In addition, the material for an organic EL device according to an embodiment may be applied in an organic EL apparatus of an active matrix using thin film transistors (TFT).

In addition, in the organic EL device 100 according to this embodiment, the driving at a low voltage with high efficiency and long life may be realized by using the material for an organic EL device according to an embodiment in an emission layer 110 or a layer among layers stacked between the emission layer 110 and a positive electrode 104.

### Examples

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

(Preparation Method)

The material for an organic EL device according to the inventive concept was synthesized by the following method.

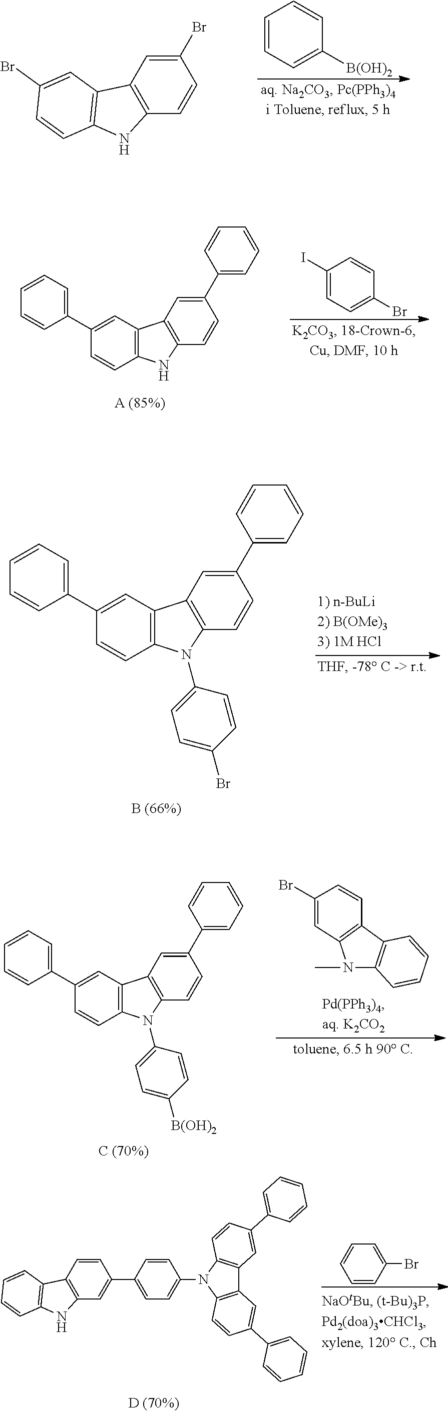

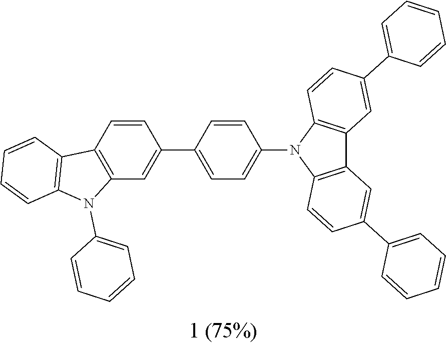 [SMILES: c1ccc(-c2ccc3c(c2)c2cc(-c4ccccc4)ccc2n3-c2ccc(-c3ccc4c5ccccc5n(-c5ccccc5)c4c3)cc2)cc1]

(Synthesis of Compound A)

Under an argon atmosphere, 10.0 g of 3,6-dibromocarbazole, 7.88 g of phenylboronic acid, 0.533 g of tetrakis(triphenylphosphine)palladium (Pd(PPh₃)₄), 131 mL of a 2 M aqueous sodium carbonate (Na₂CO₃) solution, and 65 mL of ethanol were added in a 1 L, four-necked flask, followed by stirring in 325 mL of a toluene solvent at 90° C. for 5 hours. After cooling in air, an organic layer was separated and solvents were distilled off. Then, the crude product thus obtained was recrystallized in toluene to obtain 8.35 g of Compound A as a white solid (yield 85%).

(Identification of Compound A)

The identification of Compound A was conducted by ¹H-NMR and FAB-MS. In addition, the identification of the following Compound B, Compound C, and Compound 1 was also conducted by ¹H-NMR and FAB-MS. The identification of Compound D was conducted by ¹H-NMR and FAB-MS. For the measurement of ¹H-NMR, a CDCl₃ solvent was used.

The chemical shift values of Compound A measured by the ¹H-NMR were 8.34 (dd, 1H), 8.11 (s, 1H), 7.72 (ddd, 4H), 7.69 (dd, 2H), 7.50 (dd, 2H), 7.48 (dddd, 4H), 7.34 (tt, 2H).

(Synthesis of Compound B)

Under an argon atmosphere, 4.70 g of Compound A, 6.24 g of 1-bromo-4-iodobenzene, 7.48 g of copper, 16.3 g of potassium carbonate (K₂CO₃), 2.33 g of 18-crown-6-ether, and 47 mL of DMF were added in a 200 mL, three-necked flask, followed by stirring at 190° C. for 10 hours. After cooling in air, an organic layer was separated and solvents were evaporated. Then, the crude product thus obtained was recrystallized in toluene to obtain 4.61 g of Compound B as a white solid (yield 66%).

(Identification of Compound B)

The molecular weight of Compound B measured by FAB-MS was 475.

(Synthesis of Compound C)

Under an argon atmosphere, 4.50 g of Compound B was added in a 200 mL, three-necked flask, followed by stirring in 47 mL of a THF solvent at −78° C. for 5 minutes. 7.20 mL of 1.58 M of n-butyl lithium (in an n-hexane solution) was added thereto, followed by stirring at −78° C. for 1 hour. Then, 2.11 mL of trimethoxyborane was added thereto, followed by stirring at room or ambient temperature for 2 hours. 50 mL of a 2M aqueous hydrochloric acid solution was added thereto, followed by stirring at ambient temperature for 3 hours. An organic layer was separated, and solvents were distilled off. Then, the crude product thus obtained was re-precipitated in a solvent system of ethyl acetate and hexane to obtain 2.92 g of Compound C as a white solid (yield 70%).

(Identification of Compound C)

The molecular weight of Compound C measured by FAB-MS was 440.

(Synthesis of Compound D)

Under an argon atmosphere, 3.20 g of Compound C, 1.79 g of 2-bromocarbazole, 0.589 g of tetrakis(triphenylphosphine)palladium (Pd(PPh₃)₄), 2.01 g of potassium carbonate (K₂CO₃), 26 mL of water, and 10 mL of ethanol were added in a 500 mL, three-necked flask, followed by stirring in 160 mL of a toluene solvent at 90° C. for 6.5 hours. After cooling in air, an organic layer was separated and solvents were distilled off. Then, the crude product thus obtained was recrystallized in toluene to obtain 2.86 g of Compound D as a white solid (yield 70%).

(Identification of Compound D)

The molecular weight of Compound D measured by FAB-MS was 561.

(Synthesis of Compound 1)

Under an argon atmosphere, 1.55 g of Compound D, 0.465 mL of bromobenzene, 0.172 g of tris(dibenzylideneacetone)dipalladium(O) (Pd₂(dba)₃), 0.250 g of tri-tert-butylphosphine ((t-Bu)₃P), and 0.797 g of sodium tert-butoxide were added in a 500 mL, three-necked flask, followed by stirring in 50 mL of a xylene solvent at 120° C. for 10 hours. After cooling in air, water was added, an organic layer was separated, and solvents were distilled off. Then, the crude product thus obtained was purified by silica gel column chromatography (using a mixed solvent of dichloromethane and hexane), and was recrystallized in a mixed solvent of toluene and hexane to obtain 1.32 g of Compound 1 as a white solid (yield 75%).

(Identification of Compound 1)

The chemical shift values of Compound 1 measured by the ¹H-NMR were 8.41 (d, 2H), 8.27 (d, 1H), 8.19 (d, 1H), 7.91 (d, 1H), 7.63-7.76 (m, 14H), 7.43-7.56 (m, 9H), 7.36-7.38 (m, 3H). In addition, the molecular weight of Compound 1 measured by FAB-MS was 637.

Compound 11 was manufactured according to a similar method. Organic EL devices of Examples 1 and 2 were manufactured by using Compound 1 and Compound 11 as hole transporting materials. In addition, organic EL devices of Comparative Examples 1 and 2 were manufactured by using Compound 25 and Compound 26, below, as hole transporting materials. Compound 25 is a compound including two carbazole moieties.

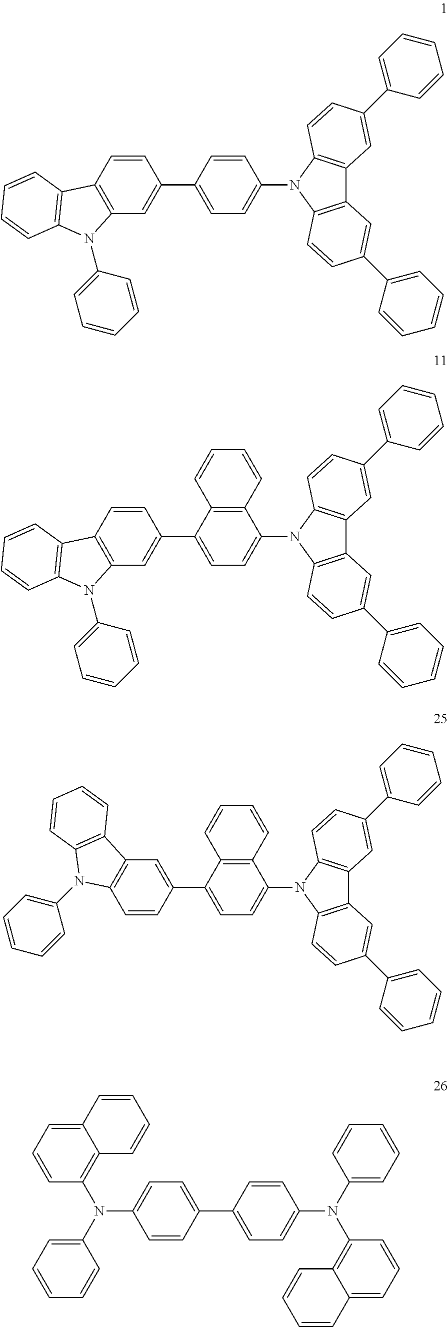 [SMILES: c1ccc(-c2ccc3c(c2)c2cc(-c4ccccc4)ccc2n3-c2ccc(-c3ccc4c5ccccc5n(-c5ccccc5)c4c3)cc2)cc1 ; c1ccc(-c2ccc3c(c2)c2cc(-c4ccccc4)ccc2n3-c2ccc(-c3ccc4c5ccccc5n(-c5ccccc5)c4c3)c3ccccc23)cc1 ; c1ccc(-c2ccc3c(c2)c2cc(-c4ccccc4)ccc2n3-c2ccc(-c3ccc4c(c3)c3ccccc3n4-c3ccccc3)c3ccccc23)cc1 ; c1ccc(N(c2ccc(-c3ccc(N(c4ccccc4)c4cccc5ccccc45)cc3)cc2)c2cccc3ccccc23)cc1]

The substrate 102 was formed by using a transparent glass substrate, the positive electrode 104 was formed using ITO having a thickness of about 150 nm, the hole injection layer 106 was formed using 2-TNATA (4,4′,4″-tris(N-(naphthyl)-N-phenylamino)triphenylamine) having a thickness of about 60 nm, the hole transport layer 108 was formed using the compounds of the Examples and the Comparative Examples and had a thickness of about 30 nm, the emission layer 110 was formed by using a material obtained by doping about 3% of TBP in ADN and had a thickness of about 25 nm, the electron transport layer 112 was formed using Alq₃ having a thickness of about 25 nm, the electron injection layer 114 was formed using LiF having a thickness of about 1 nm, and the negative electrode 116 was formed using Al having a thickness of about 100 nm.

With respect to the organic EL devices thus manufactured, voltage, emission efficiency and life were evaluated. In addition, the evaluation was performed with current density of 10 mA/cm².

TABLE 1

| | Voltage | Emission efficiency | Life |
|---|---|---|---|
| | (V) | (cd/A) | (LT50 (h)) |
| Example 1 | 4.7 | 7.5 | 3,300 |
| Example 2 | 4.9 | 6.9 | 2,800 |
| Comparative | 7.0 | 6.0 | 1,700 |
| Example 1 | | | |
| Comparative | 8.1 | 5.3 | 1,200 |
| Example 2 | | | |

As may be seen in Table 1, organic EL devices manufactured by using the compounds according to Examples 1 and 2 were driven at a lower voltage, when compared to the organic EL devices manufactured by using the compounds according to Comparative Examples 1 and 2. In addition, the emission efficiency and the lifespan were markedly increased when using the compounds according to Examples 1 and 2, when compared to those according to Comparative Examples 1 and 2. For example, the compounds in Example 1 and Comparative Example 1 both include two carbazole moieties combined or bonded through a phenylene group. However, the compound of Example 1, in which carbon at position 2 of one carbazole moiety and nitrogen at position 9 at the other carbazole moiety are combined through the phenylene group exhibited lower driving voltage, higher emission efficiency, and longer lifespan, when compared to the compound of Comparative Example 1, in which the carbon at position 3 in one carbazole moiety and nitrogen at position 9 in the other carbazole moiety are combined through the phenylene group. From the result, marked effects may be observed when combining the carbon at position 2 of one carbazole moiety and the nitrogen at position 9 at the other carbazole moiety through a connecting group. This result may be obtained by the separation of molecular orbital of highest occupied molecular orbital (HOMO) and lowest unoccupied molecular orbital (LUMO) via the above-described combining method.

In addition, when comparing Examples 1 and 2, lower driving voltage, higher emission efficiency and longer life may be obtained in the case that introducing the phenylene group as a divalent connecting group, when compared to the case that introducing a naphthalene group as the connecting group. From the results, the phenylene group may be used as the connecting group.

By way of summation and review, in application of the organic EL device to a display apparatus, low driving voltage, high efficiency, and long life of the organic EL device should be considered. For example, in a blue emitting region and a green emitting region, the emitting efficiency and the life of the organic EL device may be insufficient. To realize the driving at a low voltage with high efficiency of the organic EL device, the normalization and the stabilization of a hole transport layer may be examined. As a hole transport material used in the hole transport layer, various compounds (such as anthracene derivatives and/or aromatic amine compounds) may be used. In addition, carbazole derivatives have been suggested as favorable materials for realizing the long life of the organic EL device.

An organic EL device manufactured by using these materials may have insufficient emitting life, and an organic EL device with higher efficiency driven at a low voltage and longer emitting life may be considered. For example, the emitting efficiency of the organic EL device in the blue emitting region may be lower than the red emitting region and the green emitting region, and improvement of the emitting efficiency in the blue emitting region may be considered. To realize the driving of the organic EL device at a lower voltage with higher efficiency, a novel material may be used.

The embodiments may provide a material for an organic EL device and an organic EL device using the same, which may be driven at a low voltage, and have high efficiency and long life.

The embodiments may provide a material for an organic EL device used as an emission layer or a layer among layers stacked between the emission layer and a positive electrode, and an organic EL device using the same, which may have high efficiency and long life.

The material for an organic EL device according to an embodiment may realize an organic EL device driven at a low voltage with improved hole transport properties and electron tolerance, and having long life and high efficiency by introducing two heat resistant carbazole parts having hole transport properties through a connecting group. For example, marked effects may be obtained in a blue emitting region.

The organic EL device according to an embodiment may realize the driving at a low voltage with improved hole transport properties and electron tolerance, and having long life and high efficiency by forming an emission layer using a material for an organic EL device introducing two heat resistant carbazole parts having hole transport properties through a connecting group. For example, marked effects may be obtained in a blue emitting region.

According to an embodiment, a material for an organic EL device and an organic EL device using the same, which may be driven at a low voltage, and have high efficiency and long life may be provided. Particularly, a material for an organic EL device with high efficiency and long life in a blue emitting region, used as a layer among layers stacked between an emission layer and a positive electrode, and an organic EL device using the same may be provided. According to an embodiment, an organic EL device having improved hole transporting properties and electron tolerance, long life and high efficiency in a blue emitting region may be realized by introducing two heat resistant carbazole parts having hole transporting properties.

The embodiments may provide a material for an organic electroluminescence device and an electroluminescence device using the same, which may be driven at a low voltage, have high efficiency in a blue emitting region and have long life.

In the material for an organic EL device according to an embodiment, carbon at position 2 of one carbazole moiety and nitrogen at position 9 at the other carbazole moiety may be combined through a connecting group, and hole transport properties and electron tolerance thereof may be improved. An organic EL device using the same may realize the driving at a low voltage, high emission efficiency, and long life.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A material for an organic electroluminescence (EL) device, the material being represented by Formula 1: 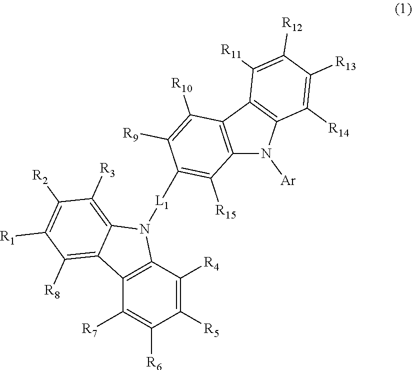
wherein, in Formula 1,
Ar is an aryl group having 6 to 30 ring carbon atoms, a heteroaryl group having 1 to 30 ring carbon atoms, or an alkyl group having 1 to 15 carbon atoms,
R₁ to R₁₅ are each independently an aryl group having 6 to 30 ring carbon atoms a heteroaryl group having 1 to 30 ring carbon atoms, an alkyl group having 1 to 15 carbon atoms, a halogen atom, a hydrogen atom, or a deuterium atom, and
L₁ is a divalent connecting group.

2. The material for an organic EL device as claimed in claim 1, wherein a plurality of adjacent ones of R₁ to R₁₄ are bound to each other and form a saturated or unsaturated ring.

3. A material for an organic electroluminescence (EL) device, the material being represented by Formula 2: 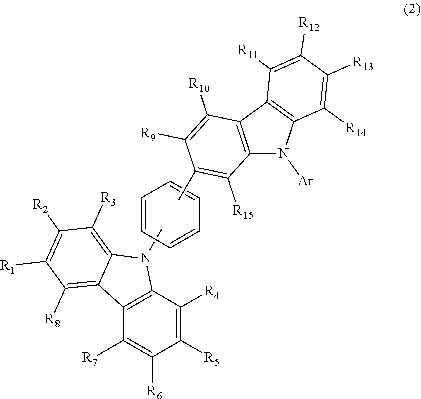
wherein, in Formula 2,
Ar is an aryl group having 6 to 30 ring carbon atoms, a heteroaryl group having 1 to 30 ring carbon atoms, or an alkyl group having 1 to 15 carbon atoms, and
R₁ to R₁₅ are each independently an aryl group having 6 to 30 ring carbon atoms, a heteroaryl group having 1 to 30 ring carbon atoms, an alkyl group having 1 to 15 carbon atoms, a halogen atom, a hydrogen atom, or a deuterium atom.

4. The material for an organic EL device as claimed in claim 3, wherein a plurality of adjacent ones of R₁ to R₁₄ are bound to each other and form a saturated or unsaturated ring.

5. An organic electroluminescence (EL) device comprising a material for an organic EL device in an emission layer or in a layer among layers stacked between the emission layer and a positive electrode, the material being represented by Formula 1: 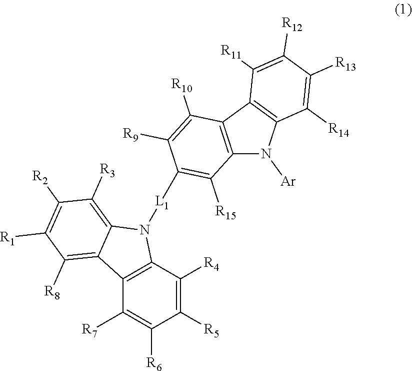
wherein, in Formula 1,
Ar is an aryl group having 6 to 30 ring carbon atoms, a heteroaryl group having 1 to 30 ring carbon atoms, or an alkyl group having 1 to 15 carbon atoms,
R₁ to R₁₅ are each independently an aryl group having 6 to 30 ring carbon atoms a heteroaryl group having 1 to 30 ring carbon atoms, an alkyl group having 1 to 15 carbon atoms, a halogen atom, a hydrogen atom, or a deuterium atom, and
L₁ is a divalent connecting group.

6. The organic electroluminescence (EL) device as claimed in claim 5, wherein Ar is a group represented by one of the following groups a-1 to a-12:

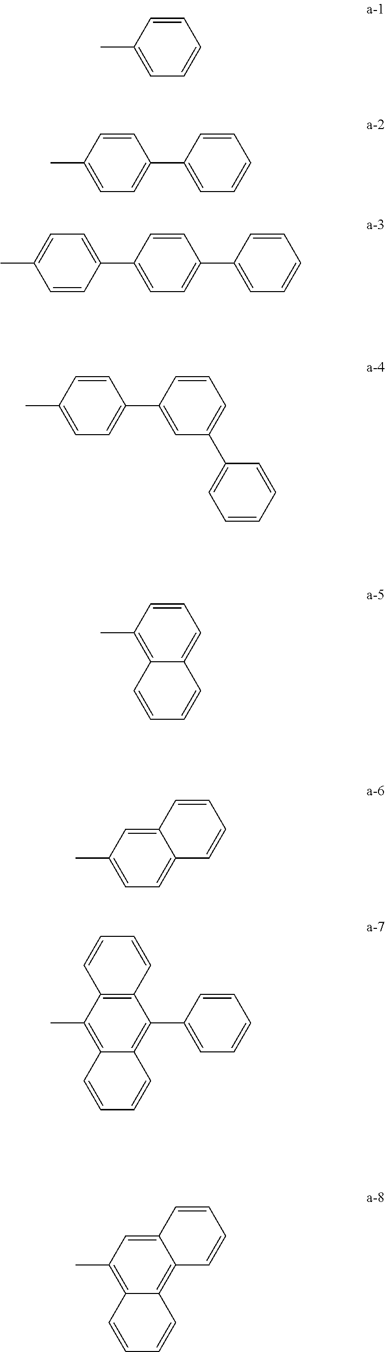

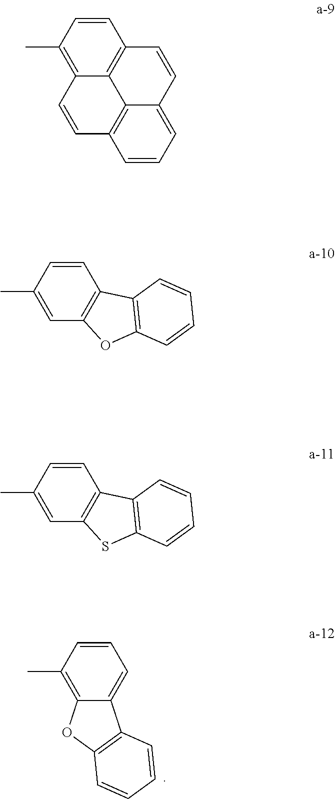

7. The organic electroluminescence (EL) device as claimed in claim 5, wherein the divalent connecting group of L₁ is a group represented by one of the following groups b-1 to b-12:

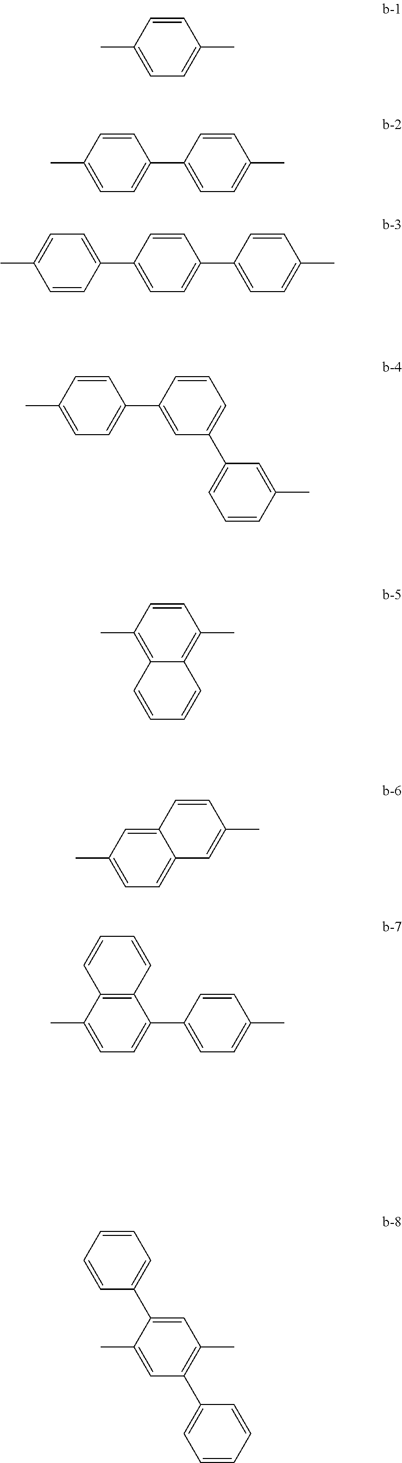

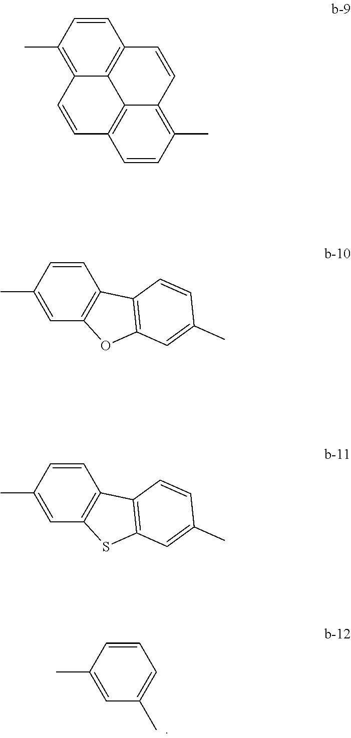

8. The organic electroluminescence (EL) device as claimed in claim 5, wherein Ar is a group represented by one of the following groups c-1 to c-25:

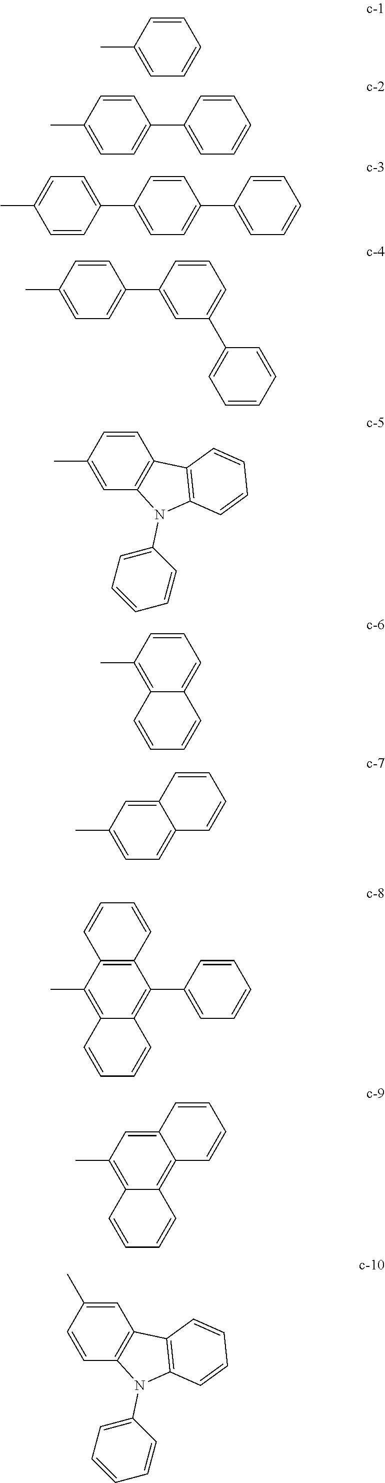

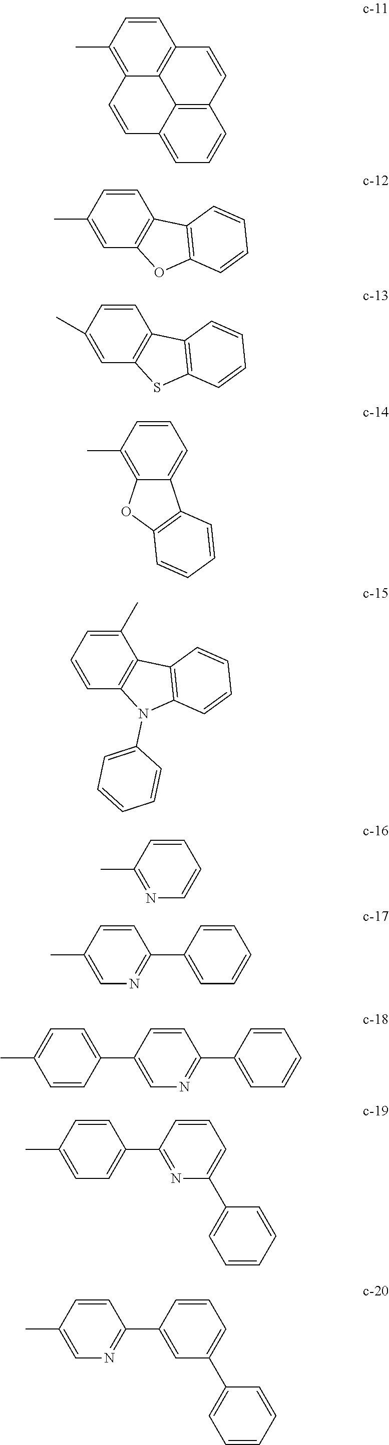

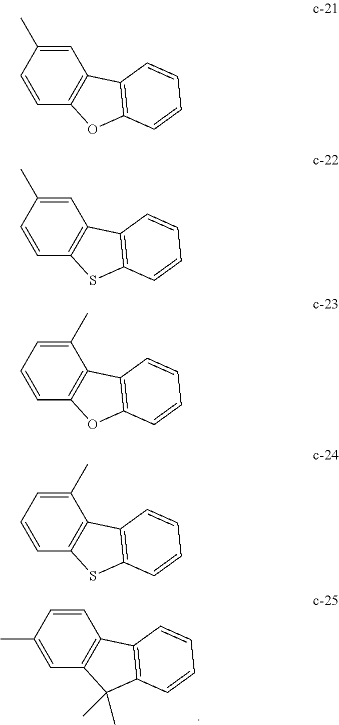

9. The organic electroluminescence (EL) device as claimed in claim 5, wherein the material represented by Formula 1 is one of the following Compounds 7 to 12:

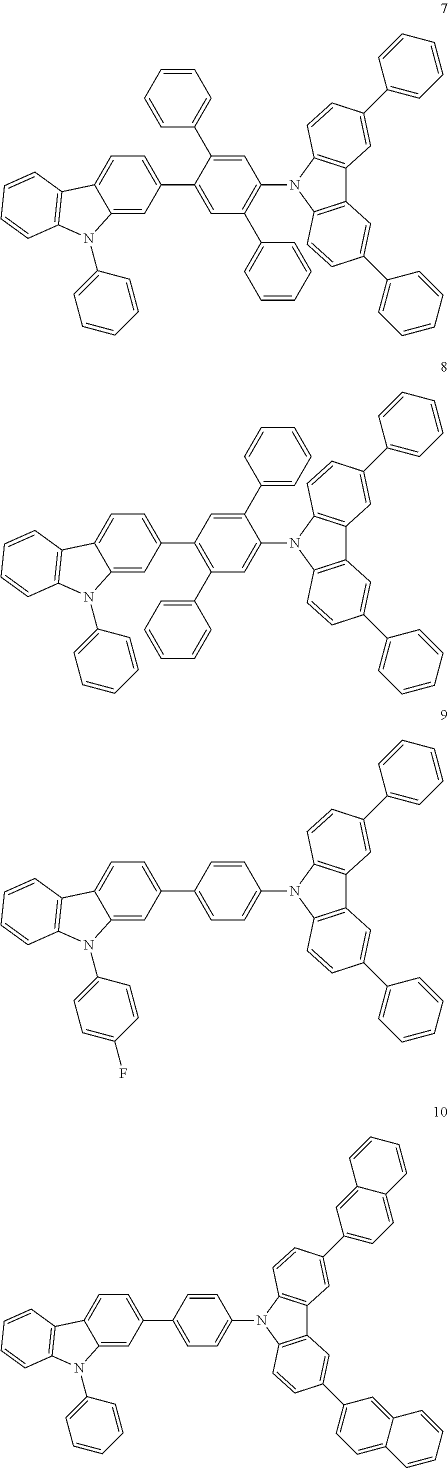

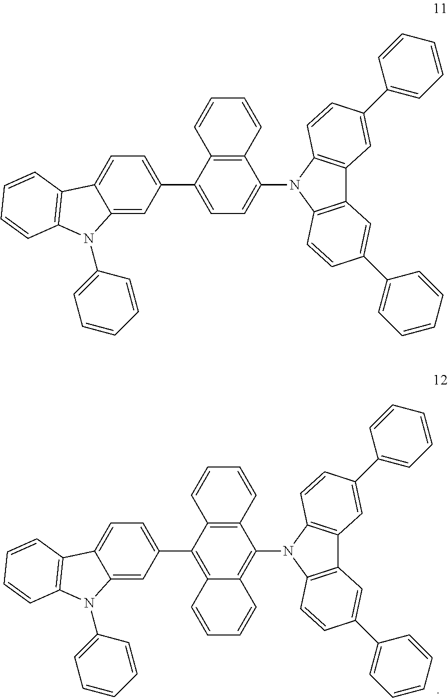 [SMILES: c1ccc(-c2ccc3c(c2)c2cc(-c4ccccc4)ccc2n3-c2ccc(-c3ccc4c5ccccc5n(-c5ccccc5)c4c3)c3ccccc23)cc1 ; c1ccc(-c2ccc3c(c2)c2cc(-c4ccccc4)ccc2n3-c2c3ccccc3c(-c3ccc4c5ccccc5n(-c5ccccc5)c4c3)c3ccccc23)cc1]

10. The organic electroluminescence (EL) device as claimed in claim 5, wherein the material represented by Formula 1 is one of the following Compounds 19 to 24:

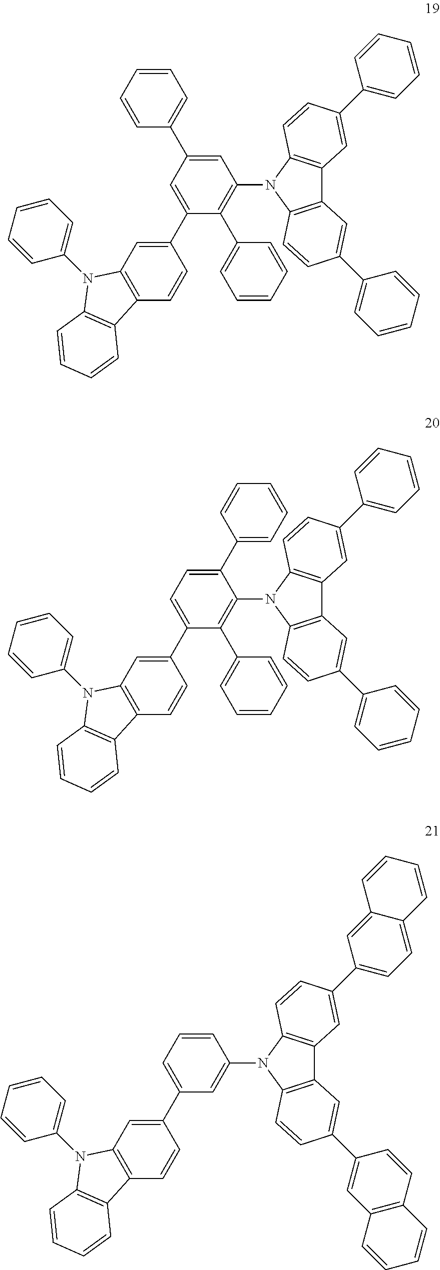 [SMILES: c1ccc(-c2cc(-c3ccc4c5ccccc5n(-c5ccccc5)c4c3)c(-c3ccccc3)c(-n3c4ccc(-c5ccccc5)cc4c4cc(-c5ccccc5)ccc43)c2)cc1 ; c1ccc(-c2ccc3c(c2)c2cc(-c4ccccc4)ccc2n3-c2c(-c3ccccc3)ccc(-c3ccc4c5ccccc5n(-c5ccccc5)c4c3)c2-c2ccccc2)cc1 ; c1ccc(-n2c3ccccc3c3ccc(-c4cccc(-n5c6ccc(-c7ccc8ccccc8c7)cc6c6cc(-c7ccc8ccccc8c7)ccc65)c4)cc32)cc1]

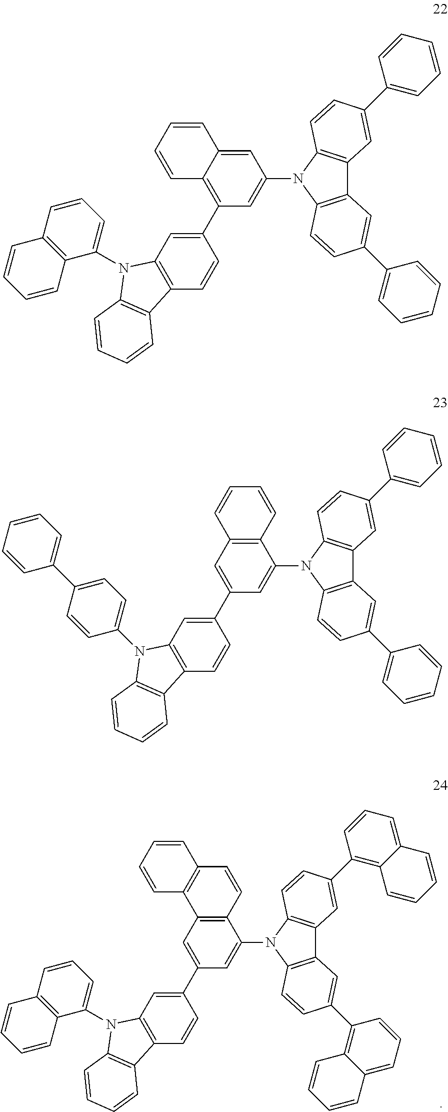 [SMILES: c1ccc(-c2ccc3c(c2)c2cc(-c4ccccc4)ccc2n3-c2cc(-c3ccc4c5ccccc5n(-c5cccc6ccccc56)c4c3)c3ccccc3c2)cc1 ; c1ccc(-c2ccc(-n3c4ccccc4c4ccc(-c5cc(-n6c7ccc(-c8ccccc8)cc7c7cc(-c8ccccc8)ccc76)c6ccccc6c5)cc43)cc2)cc1 ; c1ccc2c(-c3ccc4c(c3)c3cc(-c5cccc6ccccc56)ccc3n4-c3cc(-c4ccc5c6ccccc6n(-c6cccc7ccccc67)c5c4)cc4c3ccc3ccccc34)cccc2c1]

11. An organic electroluminescence (EL) device comprising a material for an organic EL device in an emission layer or in a layer among layers stacked between the emission layer and a positive electrode, the material being represented by Formula 2: 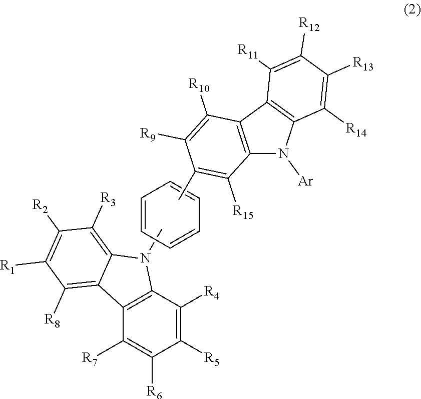
wherein, in Formula 2,
Ar is an aryl group having 6 to 30 ring carbon atoms, a heteroaryl group having 1 to 30 ring carbon atoms, or an alkyl group having 1 to 15 carbon atoms, and
R₁ to R₁₅ are each independently an aryl group having 6 to 30 ring carbon atoms, a heteroaryl group having 1 to 30 ring carbon atoms, an alkyl group having 1 to 15 carbon atoms, a halogen atom, a hydrogen atom, or a deuterium atom.

12. The organic electroluminescence (EL) device as claimed in claim 11, wherein the material represented by Formula 2 is one of the following Compounds 1 to 6:

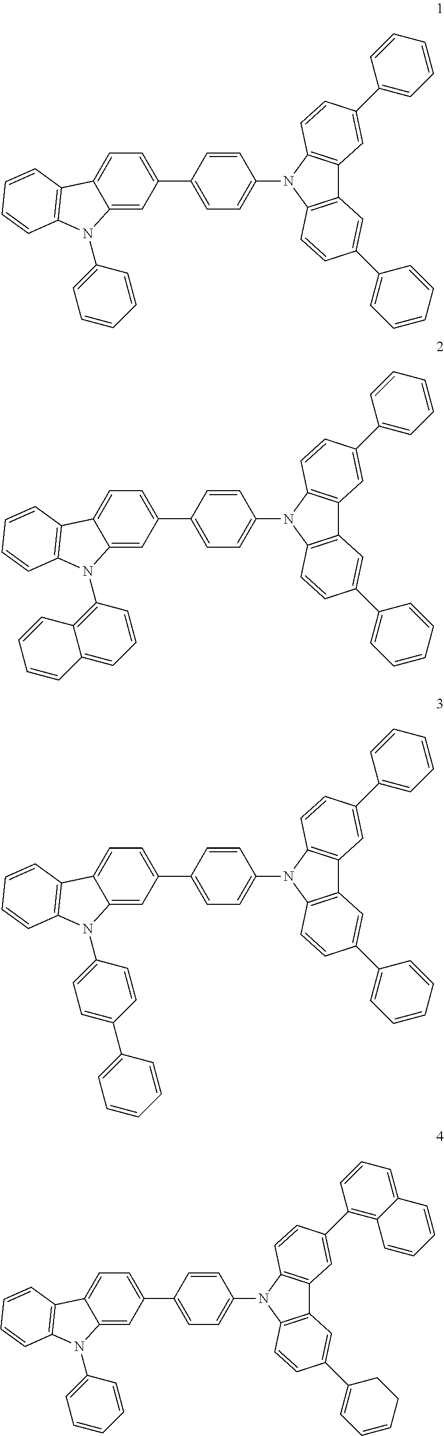

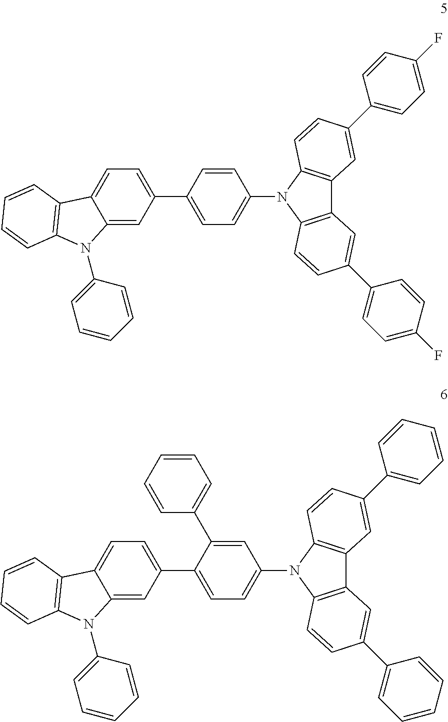 [SMILES: Fc1ccc(-c2ccc3c(c2)c2cc(-c4ccc(F)cc4)ccc2n3-c2ccc(-c3ccc4c5ccccc5n(-c5ccccc5)c4c3)cc2)cc1 ; c1ccc(-c2ccc3c(c2)c2cc(-c4ccccc4)ccc2n3-c2ccc(-c3ccc4c5ccccc5n(-c5ccccc5)c4c3)c(-c3ccccc3)c2)cc1]

13. The organic electroluminescence (EL) device as claimed in claim 11, wherein the material represented by Formula 2 is one of the following Compounds 13 to 18: 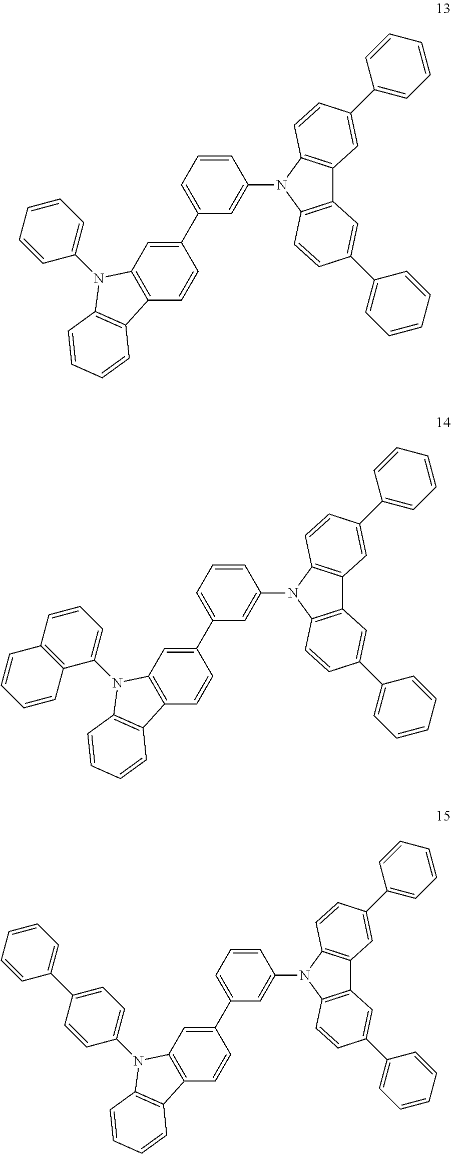 [SMILES: c1ccc(-c2ccc3c(c2)c2cc(-c4ccccc4)ccc2n3-c2cccc(-c3ccc4c5ccccc5n(-c5ccccc5)c4c3)c2)cc1 ; c1ccc(-c2ccc3c(c2)c2cc(-c4ccccc4)ccc2n3-c2cccc(-c3ccc4c5ccccc5n(-c5cccc6ccccc56)c4c3)c2)cc1 ; c1ccc(-c2ccc(-n3c4ccccc4c4ccc(-c5cccc(-n6c7ccc(-c8ccccc8)cc7c7cc(-c8ccccc8)ccc76)c5)cc43)cc2)cc1] 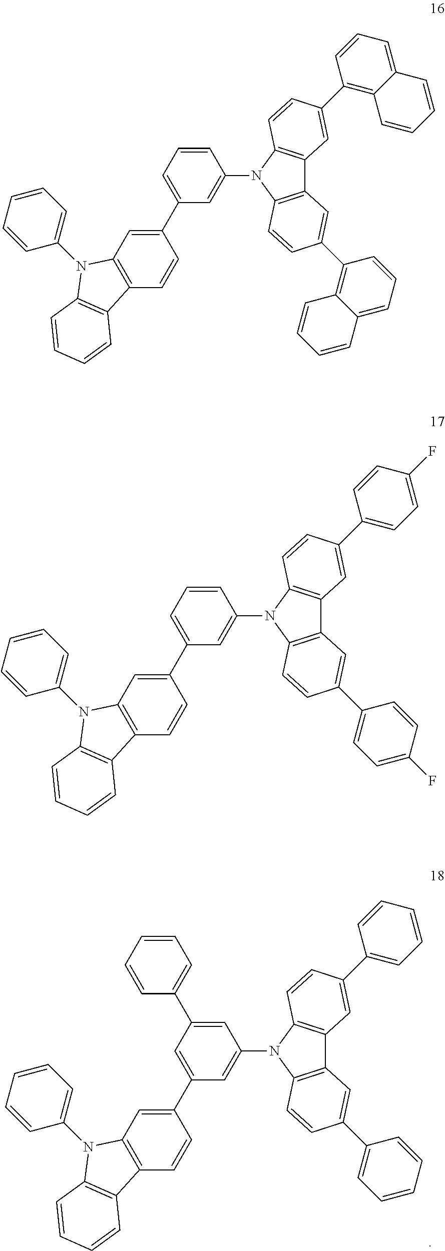 [SMILES: c1ccc(-n2c3ccccc3c3ccc(-c4cccc(-n5c6ccc(-c7cccc8ccccc78)cc6c6cc(-c7cccc8ccccc78)ccc65)c4)cc32)cc1 ; Fc1ccc(-c2ccc3c(c2)c2cc(-c4ccc(F)cc4)ccc2n3-c2cccc(-c3ccc4c5ccccc5n(-c5ccccc5)c4c3)c2)cc1 ; c1ccc(-c2cc(-c3ccc4c5ccccc5n(-c5ccccc5)c4c3)cc(-n3c4ccc(-c5ccccc5)cc4c4cc(-c5ccccc5)ccc43)c2)cc1]
